(19) United States
(12) Patent Application Publication
(10) Pub. No.: US 2025/0300057 A1
(43) Pub. Date: Sep. 25, 2025

(54) POWER CHIP EMBEDDED ENCAPSULATION MODULE

(71) Applicant: Raytrons Power Limited, HONGKONG (CN)

(72) Inventor: RAYMOND LAM WAI KIN, HONGKONG (CN)

(21) Appl. No.: 18/670,825

(22) Filed: May 22, 2024

(30) Foreign Application Priority Data
Mar. 19, 2024 (CN) 202410320154.2
Apr. 16, 2024 (CN) 202410457694.5

(51) Int. Cl. H01L 23/498; H01L 23/367; H01L 23/373; H01L 25/07

(52) U.S. Cl. CPC H01L 23/49838; H01L 23/3677; H01L 23/3735; H01L 23/49822; H01L 25/072

(57) ABSTRACT

The is a power chip embedded encapsulation module, has: a chip substrate including a first circuit substrate and an electrically conductive sheet embedded in the first circuit substrate; a ceramic substrate set on a first surface side of chip substrate; a second circuit substrate set on a second surface side of chip substrate; a plurality of power chips encapsulated between chip substrate and ceramic substrate; the first side of each power chip is electrically connected to the first circuit substrate and the electrically conductive sheet, and the second side of each power chip relative to the first side is electrically connected to ceramic substrate; a plurality of thermally conductive ceramic blocks, each of which is connected to electrically conductive sheet and ceramic substrate on opposite sides respectively; thermally conductive ceramic blocks and power chips are set alternately along the length direction of electrically conductive sheet.

### CROSS REFERENCE TO RELATED APPLICATION

This application claims priority to Chinese patent application CN 202410320154.2 with a filing date of Mar. 19, 2024 and Chinese patent application CN 202410457694.5 with a filing date of Apr. 16, 2024. The content of the aforementioned applications, including any intervening amendments thereto, are incorporated herein by reference.

### TECHNICAL FIELD

The present disclosure relates to the field of power chip encapsulation, and in particular to a power chip embedded encapsulation module.

### BACKGROUND

Power modules including power chips such as IGBT chips and/or MOSFET chips are widely used in a variety of power electronic equipment, such power chips generate a large amount of heat when working, and if the encapsulation module fails to emit the heat generated in a timely manner, it will seriously affect the power device and its surrounding electronic components. Therefore, the encapsulation module is required to have better heat dissipation performance.

In the application of switching power supply, the parasitic inductance of the power chip circuit is prone to generate a high peak voltage, which leads to greater electromagnetic interference and increase in its switching power loss. Therefore, it is necessary to minimize the parasitic inductance of power modules. In addition, with the development of power modules in the direction of miniaturization, power modules are required to have a higher degree of encapsulation integration.

### SUMMARY

The main object of the present disclosure is to provide a power chip encapsulation module with good heat dissipation performance, high integration, and low circuit impedance and parasitic effects.

In order to realize the aforestated main object, one embodiment of the present disclosure discloses a power chip embedded encapsulation module comprising:
a chip substrate comprising a first circuit substrate and an electrically conductive sheet embedded in said first circuit substrate;
a ceramic substrate, provided on a first surface side of said chip substrate;
a second circuit substrate, provided on a second surface side of said chip substrate;
a plurality of power chips encapsulated between said chip substrate and said ceramic substrate; wherein the first side of each of said power chips is electrically connected to said first circuit substrate and said electrically conductive sheet, and a second side of each said power chips relative to said first side is electrically connected to said ceramic substrate;
a plurality of thermally conductive ceramic blocks, each of which is connected to said electrically conductive sheet and said ceramic substrate on opposite sides, respectively; wherein said thermally conductive ceramic blocks and said power chips are alternately disposed along a length direction of said electrically conductive sheet.

In the above technical solution, on the one hand, the power chips and the thermally conductive ceramic blocks are encapsulated between the ceramic substrate and the chip substrate provided with electrically conductive sheets, and the thermally conductive ceramic blocks are set alternately with the power chips, and the heat generated by the power chips can be conducted to the ceramic substrate through the electrically conductive sheets and the thermally conductive ceramic blocks on the first side, and can be directly conducted to the ceramic substrate on the second side, thus realizing the three-dimensional heat dissipation of the power chips to improve the heat dissipation performance of the encapsulation module. The heat dissipation performance of the encapsulation module is improved. On the other hand, the second surface side of the chip substrate is provided with a second circuit substrate on which various circuit components can be installed, so that the power chips and the circuit components do not have to be set on the same mounting surface, which is not only conducive to improving the degree of encapsulation integration of the module, but also reduces the area of the circuit loop area of the power chip, effectively reduces the circuit impedance, and reduces the parasitic inductance effect.

Further, the size of the thermally conductive ceramic blocks located in the middle is twice the size of the thermally conductive ceramic blocks located at both ends along the length direction of said electrically conductive sheet to ensure uniformity of heat dissipation and current distribution of the module and to avoid localized overheating of the module.

Further, a side of said electrically conductive sheet is provided with a lateral projection embedded inside said first circuit substrate to connect the electrically conductive sheet more securely to the first circuit substrate.

Further, said electrically conductive sheet is provided with pins projecting to the outside of said encapsulation module to facilitate connection to an external power source.

Further, said ceramic substrate comprises a ceramic core plate and a metal conductive layer and a metal heat dissipation layer disposed on opposite sides of said ceramic core plate, respectively, said metal conductive layer being connected to said power chips and said heat conducting ceramic blocks.

Further, said metal heat dissipation layer is connected to a heat sink, said heat sink being provided with heat dissipation fins.

Further, said heat sink forms a cavity sealingly connected to said ceramic substrate to accommodate a cooling medium, and the inner wall of said cavity is provided with a capillary structure. During operation, the ceramic substrate forms an evaporation zone and the heat dissipation fins form a condensation zone, and through the evaporation-cooling cycle of the cooling medium, the heat from the ceramic substrate can be quickly and uniformly conducted to all the heat dissipation fins.

Further, said second circuit substrate is provided with a drive assembly and circuit elements.

Further, said second circuit substrate comprises multi-layer conductive circuits, and the conductive circuits of said first circuit substrate are electrically connected to the conductive circuits of said second circuit substrate, so that some of the circuit components can be encapsulated inside the second circuit substrate, further improving the integration degree of the encapsulation module.

Further, said first circuit substrate is provided with at least one set of said electrically conductive sheets, each set of said electrically conductive sheets comprising a first electrically conductive sheet and a second electrically conductive sheet, said first electrically conductive sheet and said second electrically conductive sheet being provided with said thermally conductive ceramic blocks and said power chips alternately.

Further, each of said power chips is provided with a source and a gate on a first side of the power chip, and each of said power chips is provided with a drain on a second side of the power chip, and said source and said gate are electrically connected to said electrically conductive sheet and said first circuit substrate, respectively, and said drain is electrically connected to said ceramic substrate.

In order to more clearly illustrate the objects, technical solutions and advantages of the present disclosure, the present disclosure is described in further detail below in connection with the accompanying drawings and specific embodiments.

### BRIEF DESCRIPTION OF THE DRAWINGS

FIG. 1 is a schematic view of the overall structure from a first viewpoint of Embodiment 1 of the present disclosure;

FIG. 2 is a schematic view of the overall structure from a second viewpoint of Embodiment 1 of the present disclosure;

FIG. 3 is a first exploded schematic structural view of Embodiment 1 of the present disclosure;

FIG. 4 is a schematic structural view of the ceramic substrate and the heat sink in Embodiment 1 of the present disclosure;

FIG. 5 is a second exploded schematic structural view of Embodiment 1 of the present disclosure;

FIG. 6 is a first schematic perspective structural view of the chip substrate in Embodiment 1 of the present disclosure;

FIG. 7 is a schematic structural view of the electrically conductive sheet set in Embodiment 1 of the present disclosure;

FIG. 8 is a schematic structural view of the conductive portion on the ceramic substrate in Embodiment 1 of the present disclosure;

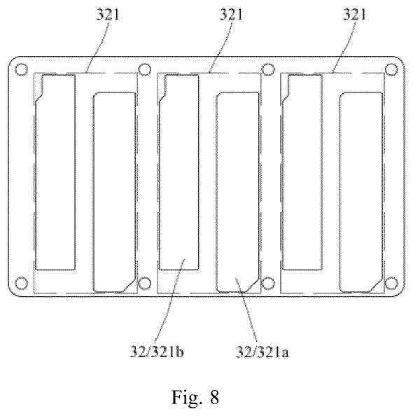

FIG. 9 is a schematic perspective structural view of the chip substrate on which the power chips and the thermally conductive ceramic blocks are provided in Embodiment 1 of the present disclosure;

FIG. 10 is a second schematic perspective structural view of the chip substrate in Embodiment 1 of the present disclosure;

FIG. 11 is a schematic front structural view of FIG. 9;

FIG. 12 is a schematic view of a conductive connection structure of the power chips in Embodiment 1 of the present disclosure;

FIG. 13 is an equivalent circuit diagram of the power chipset in Embodiment 1 of the present disclosure;

FIG. 14 is a schematic view of the overall structure of Embodiment 2 of the present disclosure;

FIG. 15 is a first exploded schematic structural view of Embodiment 2 of the present disclosure;

FIG. 16 is a second exploded schematic structural view of Embodiment 2 of the present disclosure;

FIG. 17 is a schematic perspective structural view of the chip substrate portion in Embodiment 2 of the present disclosure;

FIG. 18 is a schematic front structural view of the first surface side of the chip substrate in Embodiment 2 of the present disclosure;

FIG. 19 is a schematic front structural view of the second surface side of the chip substrate in Embodiment 2 of the present disclosure.

### DETAILED DESCRIPTION OF THE PREFERRED EMBODIMENTS

In the following description, many specific details are set forth in connection with specific embodiments in order to facilitate full understanding of the present disclosure, but it should be understood that the following specific embodiments and detailed description are for illustrative purposes only and do not limit the scope of protection of the present disclosure.

### Embodiment 1

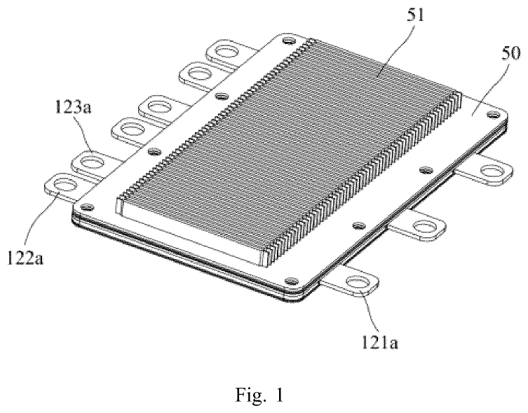

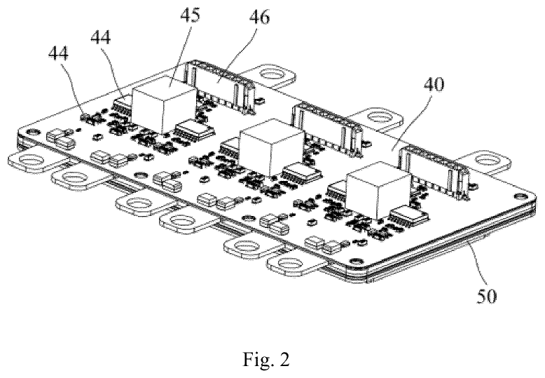

As shown in FIG. 1 to FIG. 5, the power chip embedded encapsulation module disclosed in the embodiment includes a chip substrate 10, a plurality of power chips 21, a ceramic substrate 30, and a second circuit substrate 40. Wherein, the ceramic substrate 30 is disposed on a first surface side of the chip substrate 10, the second circuit substrate 40 is disposed on a second surface side of the ceramic substrate 30, and the ceramic substrate 30 is provided with a heat sink 50 on the side facing away from the chip substrate 10.

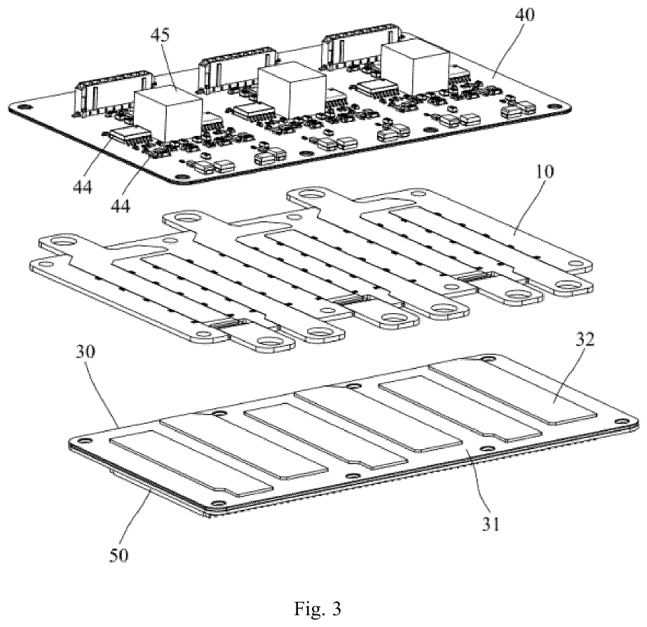

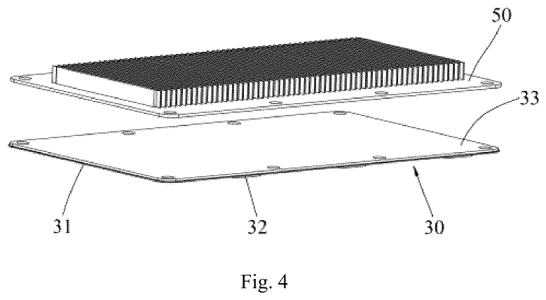

As shown in FIG. 3 and FIG. 4, the ceramic substrate 30 includes a ceramic core plate 31 and a metal conductive layer 32 and a metal heat dissipation layer 33 disposed on opposite sides of the ceramic core plate 31, respectively, and the metal conductive layer 32 and the metal heat dissipation layer 33 may typically be a copper foil layer or a composite metal layer including a copper foil layer. Wherein, the metal conductive layer 32 is provided to face the chip substrate 10, and the metal heat dissipation layer 33 is connected to the heat sink 50.

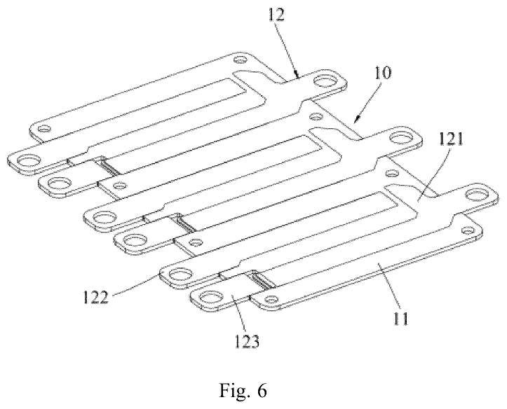

As shown in FIG. 6, the chip substrate 10 includes a first circuit substrate 11 and an electrically conductive sheet 12 embedded in the first circuit substrate 11. Wherein the first circuit substrate 11 is used for transmitting relatively small currents (e.g., control signals) and the electrically conductive sheet 12 is used for transmitting relatively large currents. The first circuit substrate 11 may be provided with a conductive circuit layer on the surface of both sides (e.g., a FR-4 circuit board with double-sided circuits), or it may be provided with a conductive circuit layer only on one side facing the ceramic substrate 30 (e.g., a FR-4 circuit board with single-sided circuits). The electrically conductive sheet 12 is preferably a copper sheet, but the present application is not limited in this respect.

The electrically conductive sheet 12 may have substantially the same thickness as the first circuit substrate 11 and penetrate the first circuit substrate 11 in the thickness direction of the first circuit substrate 11; the thickness of the electrically conductive sheet 12 may also be less than the thickness of the first circuit substrate 11 and be embedded within the first circuit substrate 11 in the thickness direction of the first circuit substrate 11. Preferably, the surface of the electrically conductive sheet 12 and the surface of the first circuit substrate 11 facing the ceramic substrate 30 are preferably flush with each other to allow for mounting of the power chip 21.

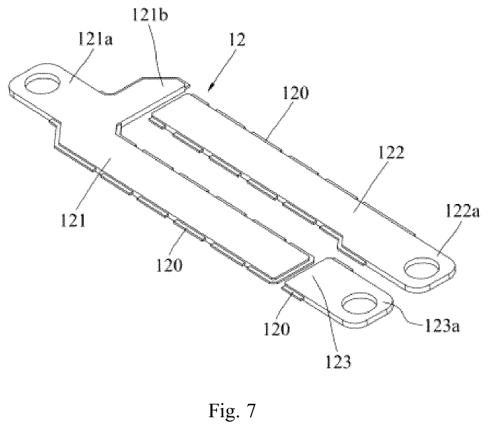

Further, as shown in FIG. 7, the side edges of the electrically conductive sheet 12 are provided with lateral projections 120 embedded inside the first circuit substrate 11 in a planar direction perpendicular to the thickness direction of the first circuit substrate 11 to more reliably secure the electrically conductive sheet 12 in the first circuit substrate 11. The thickness of the lateral projections 120 is less than the thickness of the electrically conductive sheet 12, and a plurality of spaced-apart lateral projections 120 (as shown in FIG. 7) may be provided on the side of each electrically conductive sheet 12 to achieve better fixation. Alternatively, each electrically conductive sheet 12 may have a single lateral projection that forms a continuous distribution along its multiple sides for ease of manufacturing and processing.

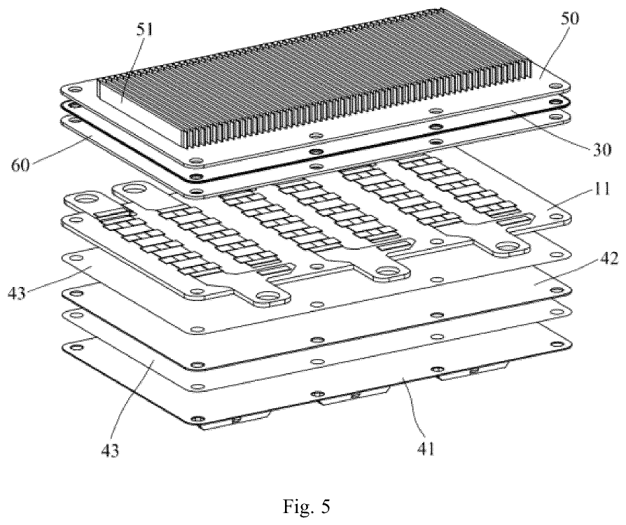

As shown in FIG. 5, the power chips 21 are encapsulated between the chip substrate 10 and the ceramic substrate 30, and the gap between the chip substrate 10 and the ceramic substrate 30 is filled with an encapsulating material layer 60 of, for example, resin. The power chips 21 may be chips such as an IGBT (Insulated Gate Bipolar Transistor), a MOSFET (Metal-Oxide Semiconductor Field Effect Transistor), a GTO (Gate Turn-Off thyristor), a GTR (Giant Transistor), a BJT (Bipolar Junction Transistor), a UJT (Unijunction Transistor), etc., and the embodiment is illustrated with the IGBT chip as an example.

In the present disclosure, a plurality of power chips 21 can form at least one power chipset 20, the chip substrate 10 is correspondingly provided with at least one set of electrically conductive sheets 12, and the metal conductive layer 32 of the ceramic substrate 30 is correspondingly provided with at least one set of conductive portions 321. Wherein the first side of the power chip 21 is electrically connected to the first circuit substrate 11 and the electrically conductive sheets 12, and the second side of the power chip 21 relative to the first side is electrically connected to the ceramic substrate 30. Further, a plurality of thermally conductive ceramic blocks 13 are also provided between the chip substrate 10 and the ceramic substrate 30, and the opposite sides of each thermally conductive ceramic block 13 are connected to the electrically conductive sheet 12 and the ceramic substrate 30, respectively; wherein the thermally conductive ceramic blocks 13 are provided alternately with the power chips 21 along the length direction of the electrically conductive sheets 12.

In the embodiment, the encapsulation module is provided with three power chipsets 20, each power chipset 20 including twenty power chips 21. The chip substrate 10 is provided with three sets of electrically conductive sheets 12, each set of electrically conductive sheets 12 including a first electrically conductive sheet 121, a second electrically conductive sheet 122, and a third electrically conductive sheet 123; the metal conductive layer 32 of the ceramic substrate 30 is provided with three sets of conductive portions 321, each set of conductive portions 321 including a first conductive portion 321a and a second conductive portion 321b. It should be noted that the specific number of electrically conductive sheets in each set of electrically conductive sheets 12 and the specific number of conductive portions in each set of conductive portions 321 can be designed according to the demand, and the present application does not limit this.

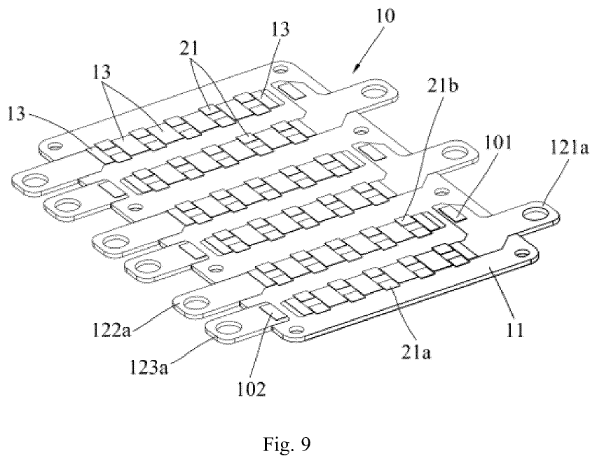

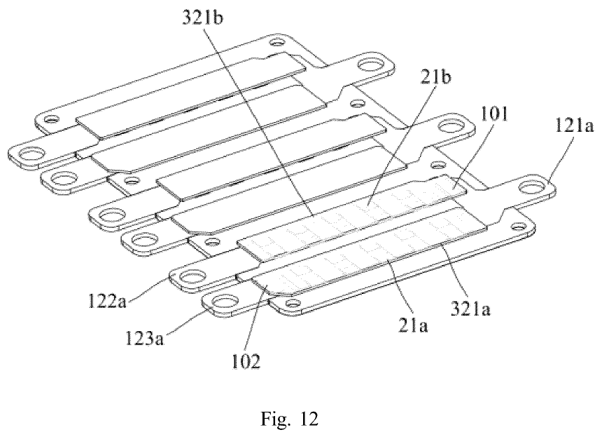

As shown in FIG. 9 to FIG. 12, a portion of the power chips 21 (e.g., ten power chips 21a) in each power chipset 20 are arranged along the length direction of the first electrically conductive sheet 121, and another portion of the power chips 21 (e.g., another ten power chips 21b) in each power chipset 20 are arranged along the length direction of the second electrically conductive sheet 122. The length directions of the first electrically conductive sheet 121 and the second electrically conductive sheet 122 may be parallel to each other.

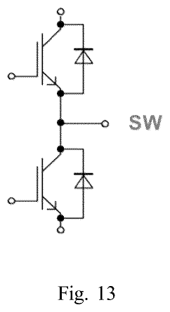

An equivalent circuit diagram of the power chipset 20 may be referred to in FIG. 13. Specifically, the first side of the power chip 21 is provided with a source S and a gate G, and the second side of the power chip 21 is provided with a drain D; wherein the source S and the gate G of the first side of the power chip 21a are electrically connected to the first electrically conductive sheet 121 and the first circuit substrate 11, respectively, and the drain D of the second side of the power chip 21a is electrically connected to the first conductive portion 321a of the ceramic substrate 30; the source S and the gate G of the first side of the power chip 21b are electrically connected to the second electrically conductive sheet 122 and the first circuit substrate 11, respectively, and the drain D of the second side of the power chip 21b is electrically connected to the second conductive portion 321b of the ceramic substrate 30.

The first electrically conductive sheet 121 has a first pin 121a projecting to the outside of the encapsulation module and a lateral extension 121b extending toward the second electrically conductive sheet 122, and a first intermediate conductive portion 101 is provided on the lateral extension 121b to connect with the second conductive portion 321b of the ceramic substrate 30, so as to realize the electrical connection between the first electrically conductive sheet 121 and the second conductive portion 321b through the first intermediate conductive portion 101; the second electrically conductive sheet 122 has a second pin 122a projecting to the outside of the encapsulation module. The first pin 121a may be a SW pin (switching pin) and the second pin 122a may be a source pin. As a variation of the embodiment, the first pin 121a may not be part of the first electrically conductive sheet 121, but may be electrically connected to the first electrically conductive sheet 121 by a connection such as soldering or screw fastening, etc., and the second pin 122a may not be part of the second electrically conductive sheet 122, but may be electrically connected to the second electrically conductive sheet 122 by a connection such as soldering or screw fastening.

The third conductive sheet 123 is provided with a second intermediate conductive portion 102 connected to the first conductive portion 321a of the ceramic substrate 30 to realize an electrical connection between the third electrically conductive sheet 123 and the first conductive portion 321a through the second intermediate conductive portion 102. The third electrically conductive sheet 123 has a third pin 123a projecting to the outside of the encapsulation module, and the third pin 123a may be a drain pin. As a variation of the embodiment, the third electrically conductive sheet 123 may not be embedded in the first circuit substrate 11, but is electrically connected to the first conductive portion 321a of the ceramic substrate 30 by a connection such as soldering or screw fastening.

The first electrically conductive sheet 121 and the second electrically conductive sheet 122 are connected with thermally conductive ceramic blocks 13, and the thermally conductive ceramic blocks 13 and the power chips 21 are alternately provided. The thermally conductive ceramic blocks 13 are connected to the metal conductive layers 32 of the ceramic substrate 30, for example, the thermally conductive ceramic blocks 13 on the first electrically conductive sheet 121 are connected to the first conductive portions 321a, and the thermally conductive ceramic blocks 13 on the second electrically conductive sheet 122 are connected to the second conductive portions 321b, and the heat of the power chips 21, after which has been conducted from the first surface to the first electrically conductive sheet 121 and the second electrically conductive sheet 122, can be further conducted through the thermally conductive ceramic block 13 to the ceramic substrate 30. Preferably, opposite sides of the thermally conductive ceramic blocks 13 may be provided with a metal layer, such as a copper foil layer, to facilitate connecting (e.g., soldering) the opposite sides of the thermally conductive ceramic blocks 13 to the electrically conductive sheet 12 and the metal conductive layer 32 of the ceramic substrate 30.

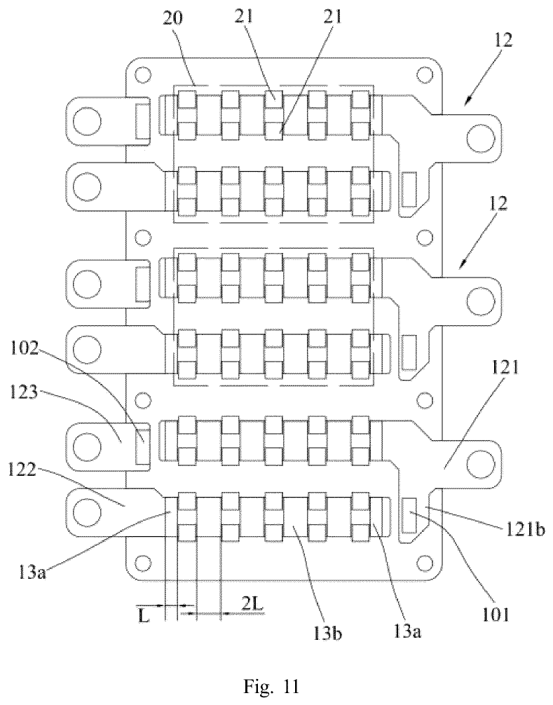

Considering that the thermally conductive ceramic blocks 13b provided between adjacent power chips 21 needs to conduct the heat of the adjacent power chips 21 at the same time, as shown in FIG. 11, the size of the thermally conductive ceramic blocks 13a disposed at the two ends are preferably one-half of the size of the thermally conductive ceramic blocks 13b disposed between the power chips 21, as shown in the length direction of the first electrically conductive sheet 121 or the second electrically conductive sheet 122. With such a design, the uniformity of heat dissipation and current distribution of the individual power chips 21 in the module can be ensured, and localized overheating of the module can be avoided.

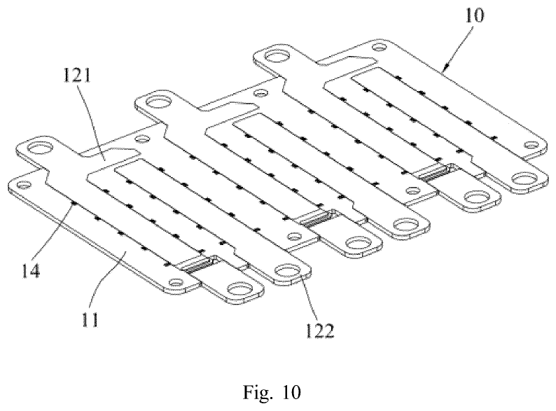

Preferably, as shown in FIG. 10, a plurality of Rg resistors (gate resistors) 14 are provided on the second surface side of the first circuit substrate 11, the plurality of Rg resistors 14 being provided in one-to-one correspondence with the plurality of power chips 21 and being electrically connected to the gate G of the corresponding power chip 21.

Referring back to FIG. 4 and FIG. 5, the metal heat dissipation layer 33 of the ceramic substrate 30 is connected to a heat sink 50, the heat sink 50 having heat dissipation fins 51. Wherein the heat sink 50 may be a conventional finned heat sink or an isothermal heat sink provided with an evaporation-condensation chamber, which is not limited by the present application.

Preferably, the heat sink 50 and its heat dissipation fins 51 each have a hollow structure cavity, which is sealed by the ceramic substrate 30 and preferably forms a negative pressure environment. Wherein, the inner wall of the cavity is preferably provided with a capillary structure. The capillary structure may be a porous metal layer formed by sintered metal powder (e.g., copper powder), a capillary woven mesh formed by using fiber filaments or metal wires (e.g., copper wires, aluminum wires), and/or capillary grooves machined on the inner wall of the cavity. Similarly, a capillary structure may be provided on the metal heat dissipation layer 33.

When the power module operates, the ceramic substrate 30 forms an evaporation zone and the heat dissipation fins 51 form a condensation zone, and through the evaporation-cooling cycle of the cooling medium, the heat of the ceramic substrate 30 can be further quickly and uniformly conducted to all of the heat dissipation fins 51.

The second circuit substrate 40 may be an FR-4 circuit board, preferably having a multi-layer structure of electrically conductive circuits to improve the integration of the encapsulation module. The second circuit substrate 40 and the first circuit substrate 11 may be regarded as an integral multi-layer circuit board, and the conductive circuits of the second circuit substrate 40 may be electrically connected to the conductive circuits of the first circuit substrate 11, e.g., they may be electrically connected through conductive perforations common in multi-layer circuit boards.

In the embodiment, the second circuit substrate 40 may comprise a first core board 41 provided with a first circuit layer and a second circuit layer on both surfaces, respectively, and a second core board 42 provided with a third circuit layer and a fourth circuit layer on both surfaces, respectively; the second core board 42 is disposed between the first core board 41 and the chip substrate 10 and is connected to the first core board 41 and the chip substrate 10 by means of an insulating bonding sheet 43. The first core board 41 and the second core board 42 may be provided with circuit components 44, such as capacitors, resistors, etc. In addition, a drive assembly 45 for the power chips 21 and an electrical connector 46 for transmitting control signals may be provided on the circuit substrate 40. A temperature sensor may also be provided on the second circuit substrate 40 to monitor the operating temperature of the module.

In the embodiment, the second circuit substrate 40 is a multi-layer structure with a first core board 41 and a second core board 42, and the circuit components can be set on the first core board 41 and the second core board 42. Compared with arranging the power chips 21 and the circuit components 44 on the same surface, by arranging the power chips 21 and the circuit components 44 on different surfaces, the length of the circuits between the power chips 21 and the circuit components 44 can be made smaller. Therefore, the encapsulation module of the embodiment can reduce the circuit loop area of the module, effectively reduce the conduction impedance, reduce the parasitic inductance effect, and thus obtain better efficiency and electrical performance, and at the same time, can make the overall power density of the encapsulation module to be greatly improved.

### Embodiment 2

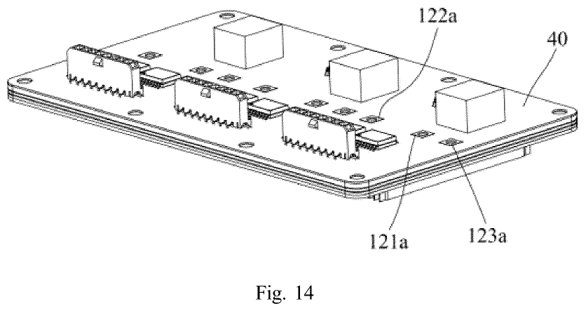

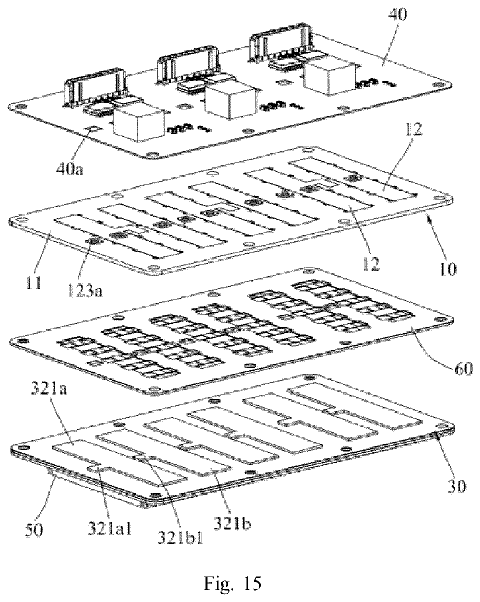

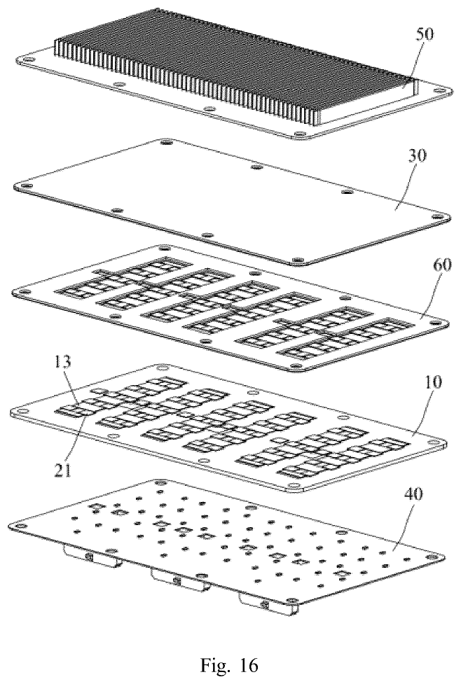

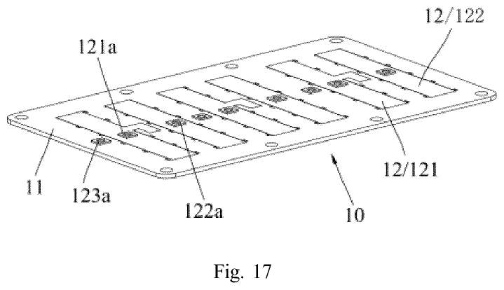

As shown in FIG. 14 to FIG. 19, in Embodiment 2, each set of electrically conductive sheets 12 includes only a first electrically conductive sheet 121 and a second electrically conductive sheet 122, the first pin 121a is provided separately from the first electrically conductive sheet 121, the second pin 122a is provided separately from the second electrically conductive sheet 122, and the first pin 121a, the second pin 122a, and the third pin 123a are provided to be exposed from the front side of the second circuit substrate 40 (i.e., a surface thereof away from the chip substrate 10), for example, exposed from a window 40a (see FIG. 15) of the second circuit substrate 40.

Wherein, the first pin 121a penetrates the second circuit substrate 40 and is electrically connected to the first electrically conductive sheet 121 (e.g., soldered to the first electrically conductive sheet 121), and the second pin 122a penetrates the second circuit substrate 40 and is electrically connected to the second electrically conductive sheet 122 (e.g., soldered to the second electrically conductive sheet 122). The third pin 123a penetrates the second circuit substrate 40, the first circuit substrate 11, and the encapsulating material layer 60 and then is electrically connected to the first conductive portion 321a of the ceramic substrate 30. Specifically, the first conductive portion 321a has a first lateral projection 321al, and the third pin 123a may be soldered to the first lateral projection 321a1.

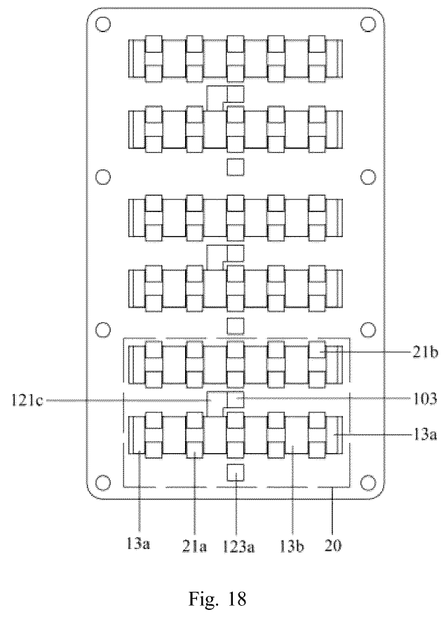

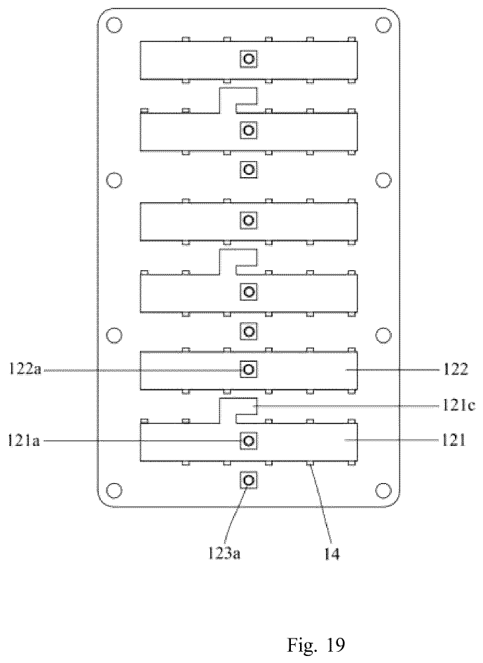

Further, as shown in FIG. 18 and FIG. 19, the first electrically conductive sheet 121 is provided with an adapter portion 121c on one side of the second electrically conductive sheet 122, and the adapter portion 121c is provided with an intermediate conductive portion 103 electrically connected to the second conductive portion 321b of the ceramic substrate 30 to realize the electrical connection between the first electrically conductive sheet 121 and the second conductive portion 321b through the intermediate conductive portion 103. Specifically, as shown in FIG. 15, the second electrically conductive portion 321b has a second lateral projection 321b1, and both ends of the intermediate electrically conductive portion 103 may be soldered connected to the second lateral projection 321b1 and the adapter portion 121c, respectively. The intermediate conductive portion 103 may be a copper block, but is not limited as such.

Additional description of Embodiment 2 can be referred to Embodiment 1 and will not be described again.

Although the present disclosure has been described above through embodiments, the above-mentioned embodiments are only used to illustrate the possible implementations of the present disclosure, and are not intended to limit the protection scope of the present disclosure, and any equivalent substitutions or variations made by a person skilled in the art in accordance with the present disclosure shall likewise be covered by the scope of protection as defined by the claims of the present disclosure.

I claim:

1. A power chip embedded encapsulation module comprising:
a chip substrate comprising a first circuit substrate and an electrically conductive sheet embedded in said first circuit substrate;
a ceramic substrate, provided on a first surface side of said chip substrate;
a second circuit substrate, provided on a second surface side of said chip substrate;
a plurality of power chips encapsulated between said chip substrate and said ceramic substrate; wherein a first side of each of said power chips is electrically connected to said first circuit substrate and said electrically conductive sheet, and a second side of each of said power chips relative to said first side is electrically connected to said ceramic substrate;
a plurality of thermally conductive ceramic blocks, each of which is connected to said electrically conductive sheet and said ceramic substrate on opposite sides, respectively; wherein said thermally conductive ceramic blocks and said power chips are alternately disposed along a length direction of said electrically conductive sheet.

2. The power chip embedded encapsulation module according to claim 1, wherein the size of the thermally conductive ceramic blocks located in the middle is twice the size of the thermally conductive ceramic blocks located at both ends along the length direction of said electrically conductive sheet.

3. The power chip embedded encapsulation module according to claim 1, wherein a side of said electrically conductive sheet is provided with a lateral projection embedded inside said first circuit substrate.

4. The power chip embedded encapsulation module according to claim 1, wherein said electrically conductive sheet is provided with pins projecting to the outside of said encapsulation module.

5. The power chip embedded encapsulation module according to claim 1, wherein said ceramic substrate comprises a ceramic core plate and a metal conductive layer and a metal heat dissipation layer disposed on opposite sides of said ceramic core plate, respectively, and wherein said metal conductive layer is connected to said power chips and said thermally conductive ceramic blocks.

6. The power chip embedded encapsulation module according to claim 5, wherein said metal heat dissipation layer is connected to a heat sink, said heat sink being provided with heat dissipation fins.

7. The power chip embedded encapsulation module according to claim 6, wherein said heat sink forms a cavity sealingly connected to said ceramic substrate to accommodate a cooling medium, said cavity having an inner wall provided with a capillary structure.

8. The power chip embedded encapsulation module according to claim 1, wherein said second circuit substrate comprises multi-layer conductive circuits, conductive circuits of said first circuit substrate being electrically connected to the conductive circuits of said second circuit substrate.

9. The power chip embedded encapsulation module according to claim 1, wherein said second circuit substrate is provided with a drive assembly and circuit elements.

10. The power chip embedded encapsulation module according to claim 1, wherein said first circuit substrate is provided with at least one set of said electrically conductive sheets, each set of said electrically conductive sheets comprising a first electrically conductive sheet and a second electrically conductive sheet, said first electrically conductive sheet and said second electrically conductive sheet being provided with said thermally conductive ceramic blocks and said power chips alternately.

11. The power chip embedded encapsulation module according to claim 1, wherein each of said power chips is provided with a source and a gate on a first side of the power chip, and each of said power chips is provided with a drain on a second side of the power chip, and said source and said gate are electrically connected to said electrically conductive sheet, and said first circuit substrate, respectively, and said drain is electrically connected to said ceramic substrate.
